(19) United States
(12) Patent Application Publication
(10) Pub. No.: US 2026/0337752 A1
(43) Pub. Date: Oct. 29, 2026

(54) METHOD FOR HEATING OF A SUBSTRATE, SUBSTRATE HEATER AND THERMAL LASER EVAPORATION SYSTEM

(71) Applicant: Max-Planck-Gesellschaft zur Förderung der Wissenschaften e.V., München (DE)

(72) Inventors: Wolfgang Braun, Bietigheim-Bissingen (DE); Johannes Arnoldus Boschker, Stuttgart (DE)

(21) Appl. No.: 19/122,397

(22) PCT Filed: Nov. 3, 2022
(86) PCT No.: PCT/EP2022/080733

§ 371 Date: Apr. 18, 2025

(51) Int. Cl. C23C 14/28; F27B 17/00; F27D 7/02; F27D 11/12; F27D 19/00; G01J 5/10; H10P 95/90

(52) U.S. Cl. CPC C23C 14/28; F27B 17/0025; F27D 7/02; F27D 11/12; F27D 19/00; G01J 5/10; H10P 95/90; F27D 2019/0003

(57) ABSTRACT

The present invention relates to a method for heating of a substrate (20), in particular a substrate (20) of a thermal laser evaporation (TLE) system (10). Further, the present invention relates to a substrate heater (30) for heating a substrate (20), in particular a substrate (20) of a TLE system (10), comprising a laser source (32) for providing a laser beam (34) and means for guiding the laser beam (34) to the substrate (20). In addition, the present invention relates to a TLE system (10), the TLE system (10) comprising a reaction chamber (12) fillable with a reaction atmosphere (14), a substrate (20) arranged in the reaction chamber (12), one or more sources (16) arranged in the reaction chamber (12), and a substrate heater (30) for providing a laser beam (34) impinging on the substrate (20) and thereby heating the substrate (20).

The present invention relates to a method for heating of a substrate, in particular a substrate of a thermal laser evaporation (TLE) system. Further, the present invention relates to a substrate heater for heating a substrate, in particular a substrate of a TLE system, comprising a laser source for providing a laser beam and means for guiding the laser beam to the substrate. In addition, the present invention relates to a TLE system, the TLE system comprising a reaction chamber fillable with a reaction atmosphere, a substrate arranged in the reaction chamber, one or more sources arranged in the reaction chamber, and a substrate heater for providing a laser beam impinging on the substrate and thereby heating the substrate.

For many modern applications, substrates are coated with evaporated and/or sublimated materials in a controlled environment, for instance for electronic devices and/or optical components. Said coatings can be provided by TLE systems, but also different evaporation and/or sublimation techniques such as direct heating of a crucible containing the respective material, electron beam heating, Pulsed laser deposition (PLD), Metalorganic chemical vapor deposition (MOCVD), or Molecular-beam epitaxy (MBE) are possible.

In all cases, an additional heating of the substrate to be coated can be of advantage. By said heating, the quality of the coating of the substrate can be enhanced, for instance due to an increased mobility of the deposited atoms and/or molecules on the surface of the substrate.

One possibility of heating said substrate can be provided by impinging a laser beam produced by a laser source onto the material of the substrate. The laser beam is absorbed at least partly by the material and hence the absorbed laser power heats the substrate.

However, it was found that a specific laser beam suitable for heating a first substrate with a first material is not automatically suitable for heating a second substrate with a second and different material. Successfully and sufficiently heating any substrate can therefore not be ensured by simply providing an arbitrary laser beam.

In view of the above, it is an object of the present invention to provide an improved method for heating of a substrate, an improved substrate heater, and an improved thermal laser evaporation system which do not have the aforementioned drawbacks of the state of the art. In particular, it is an object of the present invention to provide an improved method for heating of a substrate, an improved substrate heater, and an improved thermal laser evaporation system which provide a simple and effective heating of a specific substrate, especially adapted to a material of the respective substrate.

This object is satisfied by the respective independent patent claims. In particular, this object is satisfied by a method for heating a substrate according to independent claim 1, by a substrate heater according to independent claim 29, and by a thermal laser evaporation system according to independent claim 30. The dependent claims describe preferred embodiments of the invention. Details and advantages described with respect to the method according to the first aspect of the invention also refer to a substrate heater according to the second aspect of the invention and to a thermal laser evaporation system according to the third aspect of the invention, and vice versa, if of technical sense.

According to a first aspect of the invention the object is satisfied by a method for heating of a substrate, in particular a substrate of a thermal laser evaporation (TLE) system, comprising the steps of:
a) Determining an absorption coefficient for electromagnetic radiation of a base material of the substrate within a predetermined wavelength range;
b) Identifying an absorption band within the predetermined wavelength range, wherein the absorption band comprises a wavelength range with a lower short-wavelength end and an upper long-wavelength end with respect to the wavelength of the absorbed electromagnetic radiation;
c) Selecting a laser source providing a laser beam, wherein the laser beam comprises a laser wavelength which is within the absorption band identified in step b); and
d) Operating the laser source selected in step c) for heating the substrate.

A method according to the present invention provides heating of a substrate, in particular of a substrate to be coated with evaporated and/or sublimated material. Hence, a substrate in the sense of the present invention in particular comprises the base material, but also all layers of materials deposited later, especially during its use in any evaporation and/or sublimation system.

Basically, the present method can be used for heating a substrate independent of the actually implemented coating method. However, a TLE system is a preferred apparatus for providing evaporated and/or sublimated material, as an especially broad range of possible source materials and a high variability of flux densities of said evaporated and/or sublimated materials can be provided. Simultaneously, also a wide variety of different reaction atmospheres can be used in said TLE systems, hence allowing also a deposition of reaction products of the evaporated and/or sublimated materials with elements of the reaction atmosphere.

For ensuring a high quality of a deposition of different materials and/or reaction products, in view of for instance crystal defects of the deposited layers, in most of the cases a substrate with a suitable material is used, which has often undergone a complex surface preparation. Said materials differ, in particular in their internal structure and/or composition.

On the other hand, laser beams are an established and suitable tool for heating objects. In particular, in said TLE systems laser beams are used not only for heating but in fact for evaporating and/or sublimating materials. However, a specific property of laser beams is their narrow wavelength bandwidth of the provided laser beam, which ideally is a single wavelength only.

In combination with the aforementioned wide variety of used materials of the substrates to be coated, the narrow wavelength bandwidth of a laser beam leads to the problem that the material of an actually used substrate might not be suitable to be heated by any laser beam. For instance, the material of an actually used substrate can be essentially transparent for a wavelength of a given laser beam, and hence said laser beam passes through said substrate without any significant absorption. However, the method according to the first aspect of the present invention provides steps for solving said issue.

In the first step a) of the method according to the present invention, an absorption coefficient of a base material of the substrate to be heated is determined within a predetermined wavelength range. The base material is the material of the part of the substrate which will be illuminated when heated by the laser beam. The absorption coefficient is a property of the material especially relevant for the heating capability of the impinging laser beam, as high values of the absorption coefficient at a certain wavelength correspond to an efficient heating by absorbing electromagnetic radiation at said certain wavelength. On the other hand, low values of the absorption coefficient are linked to wavelengths of electromagnetic radiation, for which the material of the substrate is transparent or at least essentially transparent.

The predetermination of the investigated wavelength range limits the effort needed for the determination, the narrower the selected predetermined range, the lesser the effort. Preferably, the size of the range is selected with respect to the wavelengths providable by the available laser sources. A determination of the absorption coefficient in the sense of the present invention can be provided for instance as an actual measurement of the absorption coefficient, but also by using already available data of said absorption coefficient.

In summary, after execution of step a) information is present how the absorption coefficient depends on the wavelength of the impinging electromagnetic radiation in the investigated predetermined wavelength range. This allows in the subsequent step b) of the method according to the present invention to identify an absorption band within said predetermined wavelength range. An absorption band is a sub-region in the predetermined wavelength range, throughout which the absorption coefficient is higher, in particular significantly higher, than in the adjacent neighboring regions of the investigated wavelength range. In other words, an electromagnetic radiation with a wavelength larger than the lower short-wavelength end and simultaneously smaller than the upper long-wavelength end will be significantly better absorbed by the base material of the substrate than an electromagnetic radiation with a wavelength outside said absorption band. Accordingly, the base material of the substrate is essentially transparent for electromagnetic radiation with a wavelength outside said absorption band, in particular if reflections on a surface of the material are not considered.

By accordingly selecting a laser source providing a laser beam with a wavelength within said absorption band identified in step b), the afore-mentioned property of the base material with respect to absorption is considered. The laser source is actively selected such that its laser beam will be absorbed by the base material, ensured by the laser wavelength within the absorption band. However, absorbing an electromagnetic radiation also always means that electromagnetic energy is deposited into the respective base material of the substrate. An effective heating of the base material of the substrate can thereby be provided.

In the last step d) of the method according to the present invention, the actual heating of the base material of the substrate is provided. The laser source is operated and hence the laser beam comprising the laser wavelength within the absorption band is produced. By delivering said laser beam to the substrate, in other words by ensuring that the laser beam impinges onto a surface of the base material of the substrate, the substrate is heated. For said delivery, accordingly selected means including optical elements such as lenses, apertures, mirrors, light guides, and so on, preferably are provided.

In summary, by implementing the method according to the first aspect of the present invention, an effective heating of a substrate, especially of a substrate to be coated by evaporated and/or sublimated material, by an impinging laser beam can be provided. In particular, the method according to the present invention includes steps for actively selecting a laser source with respect to the absorption properties of the base material of the substrate.

Further, the method according to the present invention can be characterized in that the predetermined wavelength range used in step a) is 0.1 μm to 100 μm, in particular 0.2 μm to 20 μm. The electromagnetic spectrum is essentially unlimited. However, absorption bands of materials commonly used as base materials of substrates, and also wavelength of actually available laser sources in most of the cases are within the ultraviolet (UV), visible and/or infrared (IR) range of the electromagnetic spectrum. Hence, by limiting the predetermined wavelength range to 0.1 μm to 100 μm, in particular to 0.2 μm to 20 μm, the effort of determining the absorption coefficient in step a) of the method according to the present invention can be lowered without risk of missing information.

In addition, the method according to the present invention can comprise that the absorption band identified in step b) is linked to lattice vibrations within the base material of the substrate, in particular wherein the absorption band identified in step b) is essentially a lattice absorption band. In general, absorption of electromagnetic radiation by a material can be caused by several mechanism. For instance, the collective electron system, e.g. of a metal, can absorb electromagnetic radiation, or each singular atom of a material can absorb electromagnetic radiation. However, also the lattice formed by the plurality of atoms can absorb electromagnetic radiation and can thereby be put in oscillating motion, so called lattice vibrations or phonons. Said lattice vibrations often can be induced by absorbing electromagnetic radiation in the IR range, which is, as already mentioned above, a wavelength range in which powerful laser sources are available. In addition, as the lattice vibrations are not limited to a singular atom bur spread over the whole lattice and hence over the whole substrate, a particularly uniform heating of the substrate can be achieved.

According to another embodiment of the method according to the present invention, in step c) the laser source is selected such that the laser wavelength is within the upper 25%, preferably within the upper 10%, of the wavelength range towards the upper long-wavelength end. It has been found that the actual position of the wavelength range of the absorption band within the electromagnetic spectrum often depends on the temperature of the base material such that it shifts towards higher wavelengths. However, as the principle aim of the present invention is heating said base material, said temperature increases at least at the beginning of the execution of the method according to the present invention. By selecting the laser source such that the laser wavelength is within the upper 25%, preferably within the upper 10%, of the wavelength range towards the upper long-wavelength end, said shift of the wavelength range of the absorption band can be considered and an effective heating of the substrate can be provided independent of an actual temperature of the substrate by ensuring that the heating laser wavelength stays in the absorption band. In addition, by doing so at the same time a large, contiguous range of the absorption band can be left available for temperature measurement.

Further, the method according to the present invention can also be characterized in that the temperature of the substrate is measured by a temperature sensor during the heating of the substrate in step d). As already mentioned above, for some of the applications, in particular for some deposition reactions of evaporated and/or sublimated material onto the substrate, the substrate should provide a certain temperature. By actively measuring said temperature of the substrate using a temperature sensor, a timely feedback about the actual temperature of the substrate can be provided. The precision of the heating of the base material of the substrate can thereby be improved.

Additionally, the method according to the present invention can be improved by that the temperature sensor is a pyrometer. Pyrometers are contact free sensors which measure the temperature of an element by measuring the light emitted by said element. This allows in particular placing said pyrometers outside of reaction chambers, as long as the element to be measured is visible for the pyrometer. Hence, pyrometers are preferred temperature sensors, as an influence of the temperature measurement on any other reactions, in particular on any deposition reaction, can be avoided.

In a further improvement, the method according to the present invention can comprise that the pyrometer is sensitive to a wavelength and/or a wavelength region different, preferably additionally also distanced, to the laser wavelength. In actual embodiments, the laser beam of the laser source for heating the base material of the substrate impinges onto the same surface of the substrate, which the pyrometer investigates for the temperature measurement. By selecting a pyrometer sensitive to a wavelength and/or a wavelength region different to the laser wavelength, a negative influence on the temperature measurement by accidently measuring reflected parts of the laser beam by the pyrometer can be prohibited. A distance between the sensitivity region of the pyrometer and the laser wavelength even enhances said advantage.

The method according to the present invention can also be enhanced further by that the pyrometer is sensitive to a wavelength and/or a wavelength region which is within the wavelength range of the wavelength band identified in step b), in particular covering at least a 30%, preferably covering at least 60%, more preferably covering at least 90%, of the wavelength range of the absorption band. The ability of a material for emitting electromagnetic radiation of a certain wavelength, in particular also the radiation linked to its temperature measured by a pyrometer, is strongly linked to its absorption coefficient at said wavelength. In particular, in wavelength regions, in which the material is essentially transparent, a low or even vanishing low intensity for said emission is expected. On the other hand, for a wavelength within an absorption band, said emission will comprise high or even maximal intensity. Hence, by selecting a pyrometer sensitive to a wavelength and/or a wavelength region which is within the wavelength range of the wavelength band, the temperature measurement can be enhanced. By providing the sensitivity of the pyrometer in a part of the respective absorption band which covers the widest possible wavelength range of this absorption band without the boundaries which are most affected by thermal wavelength shifts, the temperature measurement can be made robust with respect to any shifts of the absorption band due to heating as described above. The wider the wavelength range used for temperature measurement, the higher the integrated intensity of thermal radiation that the temperature sensor, preferably pyrometer, can measure. This leads to a strong signal and thereby high signal-to-noise ratio, leading in turn to a precise temperature measurement and temperature control. Preferably, the sensitive range of the pyrometer covers as much as possible of the absorption band different to the laser wavelength of the laser beam, and hence not used by the laser beam for heating the substrate.

Preferably, for a combination of the advantages described above, the laser source is selected such that the laser wavelength is within the upper 25%, preferably within the upper 10%, of the wavelength range towards the upper long-wavelength end, and additionally the pyrometer is sensitive to a wavelength region which covers most, preferably all, of the continuous wavelength range of the absorption band limited by the laser wavelength on its long-wavelength end. By this, an interference of the laser beam and the temperature measurement provided by the pyrometer can be avoided and simultaneously a sensitive range of the pyrometer can be maximized. For instance, for Si, for which a CO₂ laser with laser wavelengths around 10 μm is suitable, as base material a pyrometer which is sensitive at 7-9 μm, for diamond, for which a CO laser with laser wavelengths around 5.5 μm is suitable, as base material a pyrometer which is sensitive at 3-5 μm, can preferably be selected.

According to another enhanced embodiment of the method according to the present invention, the temperature of the substrate measured during step d) is used for controlling the operation of the laser source in step d), in particular as input of a closed loop control of the operation of the laser source. For many, not to say most, of the applications of heated substrates the temperature of the substrate is crucial for the quality of the manufactured product, wherein both, a temperature kept constant or a temperature comprising a certain time dependence, is possible and/or required. By using the temperature information provided by the temperature measurement, a basis for an accordingly adapted control of the laser source can be provided. In particular, said temperature information can be used as input of an automatic closed loop control of the operation of the laser source.

Further, the method according to the present invention can comprise that the laser beam provided by the source selected in step c) comprises a maximum power of at least 250 W, in particular of at least 10 kW, preferably of at least 1 MW. The overall power of the laser source is the major limiting factor of the size of the substrate which can be heated by implementing the method according to the present invention. For instance, an output power of 250 W is sufficient for heating a diamond substrate of 5×5 mm² to about 2000 °C. However, a circular Si substrate with 300 mm diameter, which is one of the actually used industrial standards, has an area which is roughly 2.827 times larger. As the power needed for heating scales roughly proportionally to the area of the substrate, this leads to laser powers in the order of 1 MW, if large areas and/or high temperatures are desired. As an example of materials for substrates that can be heated up to 2000 °C or even beyond without reaching the respective melting point of the material, SiC and Al₂O₃ in particular should be mentioned.

Additionally, the method according to the present invention can be characterized in that in step d) the substrate is heated to a temperature of 250 °C or more, in particular to a temperature of 2000 °C or more. As already mentioned, an effective heating of the substrate is the main purpose of the method according to the present invention. Thereby, for some applications, a temperature of 250 °C is already sufficient. However, it is preferred to provide a heating which is capable of heating the respective substrate to higher temperatures, in particular up to at least 2000 °C, as heating to a lower temperature can be provided easily in this case by simply reducing the respective power of the laser source.

In this context, the big advantage of a laser heating source is that laser beams can be focused and thereby concentrated by an almost arbitrary degree, allowing the application of very high power densities, and thereby reaching extremely high temperatures.

According to another embodiment of the method according to the present invention, in step d) the substrate is heated to a temperature such that a wavelength of a maximum of a black-body-radiation corresponding to said temperature is outside of, preferably also distanced to, the absorption band identified in step b) in a wavelength region in which the base material of the substrate is essentially transparent. As mentioned above, in wavelength regions, in which the material is essentially transparent, a low or even vanishingly low intensity for emissions linked to the temperature of the base material of the substrate is expected. Said emissions linked to the temperature correspond to the black-body-radiation, when the respective base material is in equilibrium with its surrounding. Hence, by accordingly selecting the target temperature of the substrate, it can be provided that the heating is very efficient as on the one hand the laser beam is selected having a wavelength within an absorption band, and on the other hand radiative losses due to black-body-radiation can be minimized by selecting a temperature at which said emissions are hindered by the transparency of the base material at the respective wavelength corresponding to the maximum of the black-body-radiation.

Additionally, the method according to the present invention can be enhanced further by that the wavelength of a maximum of the black-body-radiation is lower than, preferably also distanced to, the lower short-wavelength end of the absorption band identified in step b). As mentioned above, with rising temperature of the base material the absorption band often moves to higher wavelengths. In contrast to that, the wavelength of the maximum of the black-body-radiation moves to lower wavelengths with rising temperature of the respective substrate. Hence, by selecting the temperature of the heated substrate such that the wavelength of the maximum of the corresponding black-body-radiation is lower than, preferably also distanced to, the lower short-wavelength end of the absorption band, this relative positioning of said emission wavelength and absorption wavelength range can be maintained even after corresponding wavelength shifts due to heating of the substrate have taken place.

Further, the method according to the present invention can comprise that the base material of the substrate heated by the laser is a backing for a different second material of the substrate. Not all materials to be coated can be used as base materials in the sense of the present invention, as for instance no suitable laser source is available for the absorption bands present in the respective material. However, by providing a substrate which comprises both, the material to be coated as second material and a suitable base material, which can be heated by implementing the method according to the present invention, as backing, also these second materials can be effectively heated by implementing the method according to the present invention. The accordingly selected laser beam impinges onto the backing consisting of the base material, which is effectively heated. By contact heating via thermal transport, the heating of the backing is transferred to the second material.

In the following, exemplary implementations of the method according to the present invention for explicit combinations of base materials for substrates and laser sources for their heating are described. In this sense, a base material “comprising” a certain material means that it also can comprise other materials, for instance the base material can be doped with other materials and/or can be part of an alloy.

According to a first exemplary implementation of the method according to the present invention, the base material of the substrate is based on diamond and/or diamond-like carbon, and wherein the laser source selected in step c) is a CO laser providing a laser beam with a laser wavelength of approximately 5.5 μm. Diamond and diamond-like carbon comprise a wide absorption band between approximately 2.5 μm and 6 μm. Hence, a CO laser providing a laser beam with a laser wavelength of approximately 5.5 μm is suited especially well for heating such a diamond substrate in the sense of the present invention.

The method according to the present invention can be enhanced further by that the base material of the substrate consists of diamond and/or diamond-like carbon. An especially pure substrate can thereby be provided.

According to a second exemplary implementation of the method according to the present invention, the base material of the substrate is based on SiC, and wherein the laser source selected in step c) is a CO₂ laser providing a laser beam with a laser wavelength of approximately 9.3 μm. SiC comprises a wide absorption band, the upper long-wavelength end of which is at about 10 μm. Hence, a CO₂ laser providing a laser beam with a laser wavelength of approximately 9.3 μm is also suited especially well for heating such a SIC substrate in the sense of the present invention, as said laser wavelength is near the upper long-wavelength end of the wavelength range of the absorption band, and hence shifting of the wavelength range of the absorption band due to heating the respective substrate should have no effect on said heating.

According to a third exemplary implementation of the method according to the present invention, the base material of the substrate is based on SiC, and wherein the laser source selected in step c) is a CO laser providing a laser beam with a laser wavelength of approximately 5.5 μm. As mentioned above, SiC comprises a wide absorption band which upper long-wavelength end is at about 10 μm. Hence, a CO laser providing a laser beam with a laser wavelength of approximately 5.5 μm is suited especially well for heating such a SiC substrate in the sense of the present invention. Additionally, when SiC is heated to high temperatures, Si is evaporated and will be deposited within the reaction chamber, for instance also onto an entrance window used for the laser beam heating the substrate. As a layer of pure Si is almost transparent for electromagnetic radiation with wavelengths of about 5 μm, said deposition has no or at least only neglectable impact on the heating of the substrate when a CO laser providing a laser beam with a laser wavelength of approximately 5.5 μm is used for heating the substrate.

The method according to the present invention can be enhanced further by that the base material of the substrate consists of SiC. An especially pure substrate can thereby be provided.

According to a forth exemplary implementation of the method according to the present invention, the base material of the substrate is based on an oxide and/or on Si, and wherein the laser source selected in step c) is a CO₂ laser providing a laser beam with a laser wavelength of approximately 9.3 μm and/or 10.2 μm and/or 10.6 μm. Many, not to say most, of the oxides, and also Si, used as substrates for deposition comprise a wide absorption band which is located around 10 μm. Hence, a CO₂ laser providing a laser beam with a laser wavelength of approximately 9.3 μm and/or 10.2 μm and/or 10.6 μm is suited especially well for heating such an oxide and/or Si substrate in the sense of the present invention.

The method according to the present invention can be enhanced further by that the base material of the substrate consists of the oxide or of Si. An especially pure substrate can thereby be provided.

Additionally, according to another enhanced embodiment the method according to the present invention can comprise that the oxide is Al₂O₃ or SrTiO₃ or LaAlO₃ or NdGaO₃ or DyScO₃ or MgO or GdScO₃ or Gd₃Ga₅O₁₂ or LiAlO₃ or LiAlO₂ or LiGaO₂ or LiNbO₃ or LiTaO₃ or TbScO₃ or MgAl₂O₄ or SrLaAlO₄ or SrLaGaO₄ or YAlO₃ YSC or LSAT or ZnO or SiO₂ or Ga₂O₃. This list is not complete and can be expanded by further examples of oxides as base material for substrates.

According to a fifth exemplary implementation of the method according to the present invention, the base material of the substrate is based on a nitride, and wherein the laser source selected in step c) is a CO₂ laser providing a laser beam with a laser wavelength of approximately 9.3 μm and/or 10.2 μm and/or 10.6 μm. Also many, not to say most, nitrides used as substrates for deposition comprise a wide absorption band which is located around 10 μm. Hence, a CO₂ laser providing a laser beam with a laser wavelength of approximately 9.3 μm and/or 10.2 μm and/or 10.6 μm is suited especially well for heating such nitride substrate in the sense of the present invention.

The method according to the present invention can be enhanced further by that the base material of the substrate consists of the nitride. An especially pure substrate can thereby be provided.

Additionally, according to another enhanced embodiment the method according to the present invention can comprise that the nitride is GaN or AlN. This list is not complete and can be expanded by further examples of nitrides as base material for substrates.

According to a sixth exemplary implementation of the method according to the present invention, the base material of the substrate is based on a halide, and wherein the laser source selected in step c) is a CO₂ laser providing a laser beam with a laser wavelength of approximately 9.3 μm and/or 10.2 μm and/or 10.6 μm. Also many, not to say most, halides used as substrates for deposition comprise a wide absorption band which is located around 10 μm. Hence, a CO₂ laser providing a laser beam with a laser wavelength of approximately 9.3 μm and/or 10.2 μm and/or 10.6 μm is suited especially well for heating such a halide substrate in the sense of the present invention.

The method according to the present invention can be enhanced further by that the base material of the substrate consists of the halide. An especially pure substrate can thereby be provided.

Additionally, according to another enhanced embodiment the method according to the present invention can comprise that the halide is BaF₂ or CaF₂ or KBr or KCl or NaCl or Mg₂F₂. This list is not complete and can be expanded by further examples of halides as base material for substrates.

According to a second aspect of the invention, the object is satisfied by a substrate heater for heating a substrate, in particular a substrate of a thermal laser evaporation (TLE) system, comprising a laser source for providing a laser beam and means for guiding the laser beam to the substrate, wherein the laser source of the substrate heater is selected according to step a) to c) of the method according to the first aspect of the present invention, and wherein the substrate heater is constructed to carry out step d) of the according to the first aspect of the present invention.

In particular, the substrate heater can provide an effective heating of the respective substrate, especially by selecting the used laser source with respect to the base material of the substrate to be heated. This is provided by implementing the method according to the first aspect of the present invention when preparing and using the substrate heater according to the second aspect of the present invention. By that, the substrate heater according to the second aspect of the present invention comprises all advantages already described above with respect to the method according to the first aspect of the present invention.

According to a third aspect of the present invention, the object is satisfied by a thermal laser evaporation (TLE) system, the TLE system comprising a reaction chamber fillable with a reaction atmosphere, a substrate arranged in the reaction chamber, one or more sources arranged in the reaction chamber, and a substrate heater for providing a laser beam impinging on the substrate and thereby heating the substrate, wherein the substrate heater is constructed according to the second aspect of the present invention. The substrate heater according to the second aspect of the present invention implements the method according to the first aspect of the present invention. In summary, the TLE system according to the third aspect of the present invention comprises all advantages already described above with respect to the method according to the first aspect of the present invention and with respect to the substrate heater according to the second aspect of the present invention.

In a TLE system according to the present invention, laser beams are used for both, evaporating or sublimating a source material, and heating of the material of the substrate, respectively. Such TLE systems are known in general. Source material evaporated and/or sublimated by an impinging source laser beam is deposited onto a substrate provided as target. The substrate heater according to the second aspect of the present invention, which implements the method according to the first aspect of the present invention, is used for heating the base material of the substrate.

The source material is provided as source element arranged in a source within the reaction chamber, wherein one or more sources are possible, in particular providing the same and/or different source materials. The source laser beam impinges onto a surface, in most of the cases a top surface, of the source element, providing flux of evaporated or sublimated source material.

The source and the substrate are arranged within a reaction chamber, which is sealable against ambient atmosphere and fillable with a reaction atmosphere. Said reaction atmosphere can be vacuum, in particular as low as 10⁻¹² hPa or even lower, or comprise reaction gases at pressures suitable for the material to be deposited, for instance a reaction gas providing oxygen for a deposition of an oxide of sublimated source material. Maximum values tested with a working distance of 60 mm so far are as high as 10⁻² hPa. Still higher values are likely possible as deposition was possible without problems at 10⁻² hPa.

The invention will be explained in detail in the following by means of embodiments and with reference to the drawings. In particular, in the figures are shown:

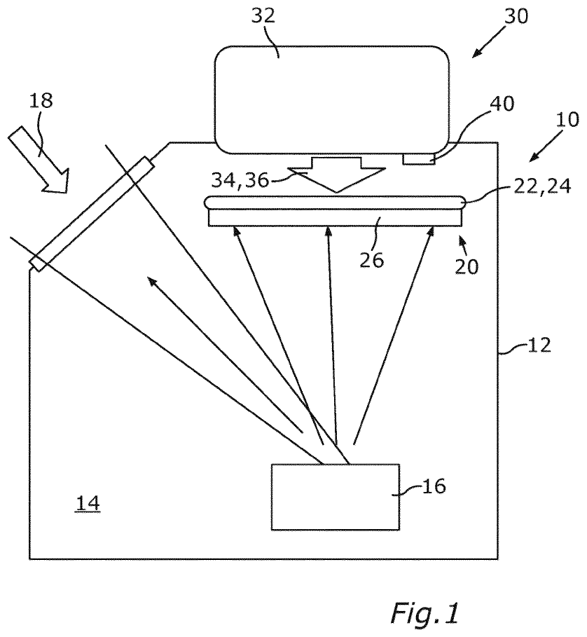

FIG. 1 A schematic view of a TLE system according to the present invention,

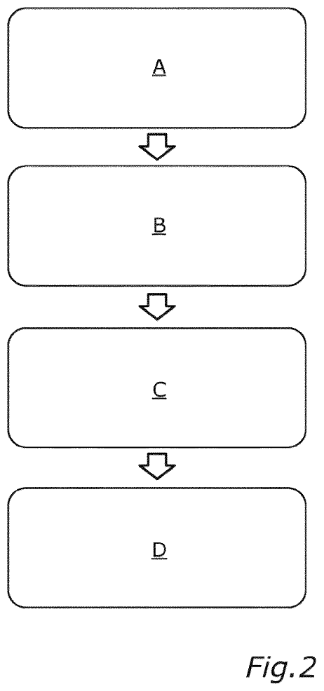

FIG. 2 A schematic view of a method according to the present invention,

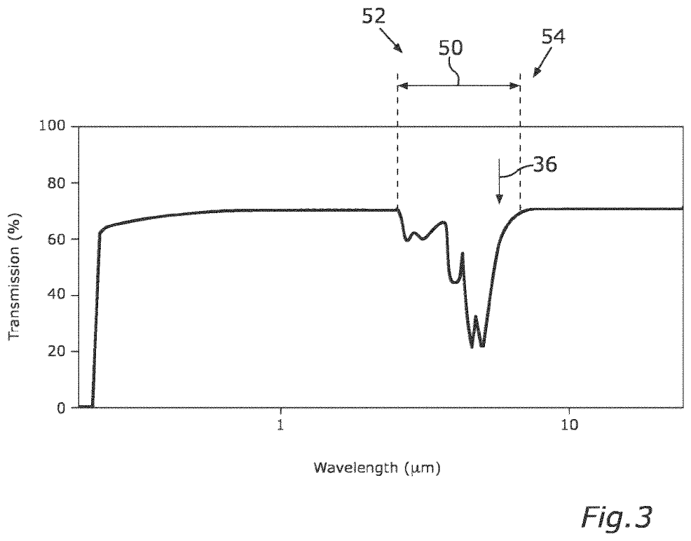

FIG. 3 A transmission spectrum of diamond,

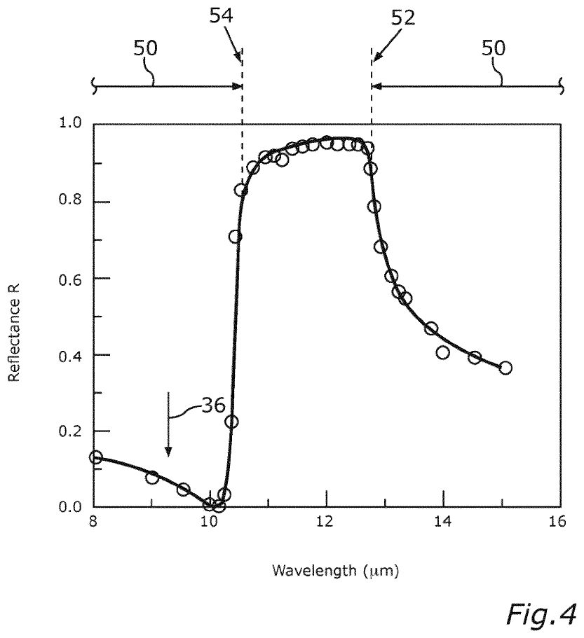

FIG. 4 A reflectance spectrum of SiC,

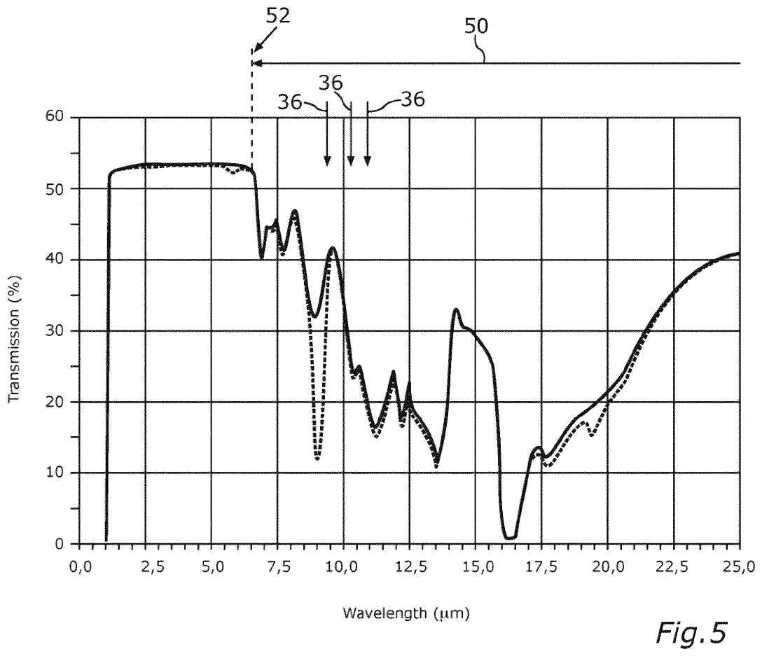

FIG. 5 A transmission spectrum of two types of Si, and

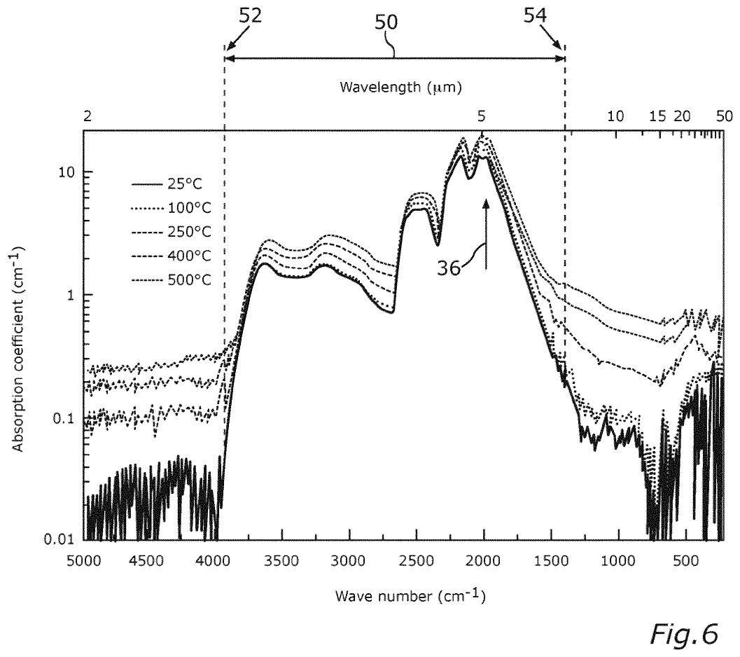

FIG. 6 Absorption spectra of diamond for different temperatures.

FIG. 1 shows a schematic view of a TLE system 10 according to the present invention, comprising the most basic elements. Within a reaction chamber 12 filled with a reaction atmosphere 14, a source 16 provides one ore more source materials to be evaporated and/or sublimated. A source laser beam 18 impinges onto the source 16 for the intended evaporation and/or sublimation of the respective material of the source 16. The evaporated and/or sublimated material of the source 16 is indicated by arrows originating from the source 16.

Further, a substrate 20 to be coated is arranged in the reaction chamber 14. In the depicted embodiment of the TLE system 10, the substrate 20 comprises a second material 26 for the actual deposition arranged at a backing 24 consisting of a base material 22, which can be heated especially effectively by a dedicated substrate heater 30 according to the present invention.

The substrate heater 30 comprises a laser source 32 which is selected by implementing a method according to the present invention. Said method is schematically depicted in FIG. 2 and will be described in the following.

In a first step a) A of the method, an absorption coefficient of the base material 22 of the substrate 20 to be heated is determined. For limiting the effort, the determination of the absorption coefficient is carried out in a predetermined wavelength range, for instance between 0.1 μm and 100 μm, in particular between 0.2 μm and 20 μm. Hence, an information is presented, how the base material 22 reacts to impinging electromagnetic radiation with different wavelengths. Namely, whether and how effectively it will absorb said radiation, or whether base material 22 is more or less transparent for the respective radiation, which will then pass through the base material 22 essentially unaffected.

This information provided in step a) A allows in the subsequent step b) B to identify an absorption band 50, in other words a wavelength range starting at a lower short-wavelength end 52 and continuously extending up to an upper long-wavelength end 54, in which the absorption coefficient is increased. Such an absorption band 50 is hence a wavelength range which is especially suitable for a heating by an accordingly provided electromagnetic radiation. An essentially effective heating of the substrate 20 can be provided, if the absorption band 50 is linked to lattice vibrations within the base material 22.

Hence, in the next step c) C of the method according to the present invention, the laser source 32 of the substrate heater 30 is selected according to the information provided in the previous steps a), b) A, B. Namely, a laser source 32 is selected such that the laser wavelength 36 of the laser beam 34 provided by the laser source 32 is within the identified absorption band 50, in particular within the upper 25%, preferably within the upper 10%, of the wavelength range towards the upper long-wavelength end 54 of the absorption band 50. Thereby, an increased, preferably maximized, absorption of the laser beam 34 by the base material 22 of the substrate 20 is ensured and hence an effective heating of the substrate 20 can be provided.

In the final step d) D of the method according to the present invention, the actual heating of the substrate 20, in particular of the base material 22 of the substrate 20, takes place. The laser source 30 is operated, the laser beam 34 impinges onto the base material 22 and hence is heated. Preferably, the laser source 32 provides a laser beam 34 with a maximum power of at least 250 W, in particular of at least 10 KW, preferably of at least 1 MW. In the embodiment depicted in FIG. 1, the base material 22 forms a backing 24, the second material 26 of the substrate 20 actually used for the deposition of evaporated and/or sublimated material of the source 16 is hence heated indirectly by the physical contact to the base material 22.

In step d) D, the substrate 20 can be heated up to a temperature of 250 °C, preferably up to 2000 °C or even beyond. Additionally, or alternatively, the substrate 20 can be heated to a temperature such that a wavelength of a maximum of a black-body-radiation corresponding to said temperature is outside of, in particular also distanced to and/or lower and hence at shorter wavelengths than the absorption band 50. In particular, the maximum of a black-body-radiation preferably should be in a wavelength region in which the base material 22 of the substrate 20 is essentially transparent for suppressing radiative cooling of the substrate.

Additionally, in FIG. 1 also a pyrometer 40 for measuring a temperature of the substrate 20, in particular of the base material 22, is depicted. The pyrometer 40 can be provided as part of the substrate heater 30 or as an additional element of the TLE system 10. Basically, the pyrometer 40 is already a preferred embodiment, any suitable sensor for measuring said temperature can be implemented. In an even further preferred embodiment, the pyrometer is arranged on the optical axis of the heating laser, via a beam splitter, to collect intensity from the entire back surface area of the substrate irradiated by the heating laser.

For avoiding a direct influence of the laser beam 34 on the pyrometer 40, said pyrometer can be selected such that is sensitive to a wavelength and/or a wavelength region different, preferably additionally also distanced, to the laser wavelength 36. Additionally, or alternatively, the pyrometer 40 can also be selected such that it is sensitive to a wavelength and/or a wavelength region which covers covering at least a 30%, preferably covering at least 60%, more preferably covering at least 90%, of the wavelength range of the absorption band 50, as the base material 22 will emit thermal radiation in this wavelength range.

Further, the measured temperature can be used as input for controlling the operation of the laser source 32. In particular, a closed loop control of the operation of the laser source 32 can be provided.

FIGS. 3 and 5 depict transmission spectra, FIG. 4 a reflectance spectrum of possible base materials 22, namely diamond (FIG. 3), SiC (FIG. 4) and Si (FIG. 5), wherein for Si a respective spectrum for p-type Si (solid line) and n-type Si (dashed line) are shown. As a low value of the depicted transmission coefficient and likewise also a low value of the depicted reflectance coefficient correspond to an increased value of the absorption coefficient, said spectra can also interpreted as representations of the absorption coefficient.

FIG. 3 depicts a transmission spectrum of diamond. Diamond is a possible base material 22 for a substrate 20, in particular in TLE systems 10. The absorption band 50 of diamond identified during execution of the method according to the present invention extends from a lower short-wavelength end 52 at around 3.5 μm to an upper long-wavelength end 54 at around 7.5 μm. Additionally depicted is a laser wavelength 36 of a CO laser at about 5.5 μm, clearly located within the absorption band 50. Hence, a CO laser is a laser source 32 that can be selected when carrying out a method according to the invention for a substrate 20 whose base material 22 comprises or consists of diamond. In particular, the laser wavelength 36 of said CO laser is within the upper 25% of the wavelength range of the absorption band 50 towards its upper long-wavelength end 54, which is especially preferable due to a shift of the absorption band 50 towards higher wavelengths with rising temperature of the heated base material 22 (see FIGS. 1 and 6).

In FIG. 4, a cutout of a reflectance spectrum of SiC is shown. Also SiC is a possible base material 22 for a substrate 20, in particular in TLE systems 10. As clearly visible, the reflectance of this base material 22 is very high, in particular almost perfect, between about 10 μm and 13 μm, Adjacent to this wavelength range of high reflectivity, absorption bands 50 are located, one of them ending with its upper long-wavelength end 54 at around 10 μm, the other one starting with its lower short-wavelength end 52 at around 13 μm.

Similar to FIG. 4, a laser wavelength 36 of the laser beam 34 of a laser source 32 possibly selected during the method according to the present invention is depicted, which clearly is within the absorption band 50. However, in the present case shown in FIG. 4, it is a CO₂ laser with a laser wavelength at about 9.3 μm. Hence, a CO₂ laser is a laser source 32 that can be selected when carrying out a method according to the invention for a substrate 20, the base material 22 of which comprises or consists of SiC.

In particular, the laser wavelength 36 of said CO laser is within the upper 25% of the wavelength range of the absorption band 50 towards its upper long-wavelength end 54, which is especially preferable due to a shift of the absorption band 50 towards higher wavelengths with rising temperature of the heated base material 22 (see FIGS. 1 and 6). Additionally, also the already mentioned CO laser can be selected as suitable laser source 32, the absorption band 50 ending at about 7 μm extends well below the laser wavelength 36 of said CO laser of 5.5 μm.

FIG. 5 depicts transmission spectra of two types of substrates 20 comprising Si as base material 22 (see FIG. 1), namely p-type Si (solid line) and n-type Si (dashed line). It is clearly visible that different doping of intrinsic Si leads to a slightly different transmission spectrum. However, general features including for instance the lower short-wavelength end 52 of the absorption spectrum 50 corresponding to the depicted transmission spectrum stay constant. Also, Si, independent whether intrinsic or somehow doped, is a possible base material 22 for a substrate 20, in particular in TLE systems 10. The absorption band 50 of Si identified during execution of the method according to the present invention starts from a lower short-wavelength end 52 at around 6.5 μm and extends even beyond the depicted range of the transmission spectrum. Additionally, laser wavelengths 36 of a CO₂ laser at about 9.3, μm 10.2 μm and 10.6 μm is depicted, which clearly are within the absorption band 50, with the highest absorption for 10.6 μm. Hence, a CO₂ laser is a laser source 32 that can be selected when carrying out a method according to the invention for a substrate 20 whose base material 22 comprises or consists of Si. No economic high-power lasers presently are available at the best absorption between 16 and 16.5 μm, or towards the upper higher wavelength end of the spectrum. The CO₂ laser at 10.6 μm wavelength is therefore currently the best result of the method according to the invention for Si.

Despite not depicted, the features described with respect to FIG. 5 also hold true for substrates 20 with an oxide, for instance Al₂O₃ or SrTiO₃or LaAlO₃ or NdGaO₃ or DyScO₃ or MgO or GdScO₃, or with a nitride, such as for instance GaN or AlN, or with a halide, for instance BaF₂ or CaF₂ or KBr or KCl or NaCl or Mg₂F₂ as base material 22. In particular, also oxides, nitrides and halides can comprise a broad absorption band 50 with a lower short-wavelength end 52 well below 10 μm and an upper long-wavelength end 54 well above 10 μm. Hence, also for these base materials the aforementioned CO₂ laser with its laser wavelengths of about 9.3, μm 10.2 μm and 10.6 μm can be selected as laser source 32 during execution of the method according to the present invention for a substrate 20 with a base material 22 comprising or consisting of an oxide or a nitride or a halide.

FIG. 6 shows several absorption spectra for substrates 20 with a base material 22 comprising diamond, which essentially differ by the temperature of the substrate 20 during the determination of the absorption coefficients. Results for measurements at 25 °C, 100 °C, 250 °C 400 °C and 500 °C are shown. Additionally, an approximate indication of a position of the lower short-wavelength end 52 and of the upper long-wavelength end 54 of the absorption band 50 is included.

It is clearly visible that the actual upper long-wavelength end 54 of the absorption band 50 slightly shifts to higher wavelengths with rising temperature of the substrate 20. Hence, by selecting the laser source 32 (see FIG. 1) such that its laser wavelength 36 is within the upper 25% of the absorption band 50, leaving said absorption band 50 of the laser wavelength 36 due to the aforementioned temperature shift can be avoided.

### List of References

10 TLE system

12 reaction chamber

14 reaction atmosphere

16 source

18 source laser beam

20 substrate

22 base material

24 backing

26 second material

30 substrate heater

32 laser source

34 laser beam

36 laser wavelength

40 pyrometer

50 absorption band

52 lower short-wavelength end

54 upper long-wavelength end

A step a) of the method according to the present invention

B step b) of the method according to the present invention

C step c) of the method according to the present invention

D step d) of the method according to the present invention

1-30. (canceled)

31. Method for heating of a substrate, comprising the steps of:
a) Determining an absorption coefficient for electromagnetic radiation of a base material of the substrate within a predetermined wavelength range; (A)
b) Identifying an absorption band within the predetermined wavelength range, wherein the absorption band comprises a wavelength range with a lower short-wavelength end and an upper long-wavelength end with respect to the wavelength of the absorbed electromagnetic radiation; (B)
c) Selecting a laser source providing a laser beam, wherein the laser beam comprises a laser wavelength which is within the absorption band identified in step b) (B); (C) and
d) Operating the laser source selected in step c) (C) for heating the substrate. (D)

32. Method according to claim 31,
wherein the predetermined wavelength range used in step a) (A) is 0.1 μm to 100 μm.

33. Method according to claim 31,
wherein the absorption band identified in step b) (B) is linked to lattice vibrations within the base material of the substrate.

34. Method according to one of the preceding claims 31,
wherein in step c) (C) the laser source is selected such that the laser wavelength is within the upper 25% of the wavelength range towards the upper long-wavelength end.

35. Method according to one of the preceding claims 31,
wherein the temperature of the substrate is measured by a temperature sensor during the heating of the substrate in step d) (D).

36. Method according to claim 35,
wherein the temperature sensor is a pyrometer.

37. Method according to claim 36,
wherein the pyrometer is sensitive to a wavelength and/or a wavelength region different to the laser wavelength.

38. Method according to claim 36,
wherein the pyrometer is sensitive to a wavelength and/or a wavelength region which is within the wavelength range of the wavelength band identified in step b) (B).

39. Method according to one of the claims 35,
wherein the temperature of the substrate measured during step d) (D) is used for controlling the operation of the laser source in step d) (D).

40. Method according to one of the preceding claims 31,
wherein the laser beam provided by the laser source selected in step c) (C) comprises a maximum power of at least 250 W.

41. Method according to one of the preceding claims 31,
wherein in step d) (D) the substrate is heated to a temperature of 250 °C or more.

42. Method according to one of the preceding claims 31,
wherein in step d) (D) the substrate is heated to a temperature such that a wavelength of a maximum of a black-body-radiation corresponding to said temperature is outside of the absorption band identified in step b) (B) in a wavelength region in which the base material of the substrate is essentially transparent.

43. Method according to claim 42,
wherein the wavelength of a maximum of the black-body-radiation is lower than the lower short-wavelength end of the absorption band identified in step b) (B).

44. Method according to one of the preceding claims 31,
wherein the base material of the substrate heated by the laser is a backing for a different second material of the substrate.

45. Method according to one of the preceding claims 31,
wherein the base material of the substrate is based on diamond and/or diamond-like carbon, and wherein the laser source selected in step c) (C) is a CO laser providing a laser beam with a laser wavelength of approximately 5.5 μm.

46. Method according to claim 45,
wherein the base material of the substrate consists of diamond and/or diamond-like carbon.

47. Method according to one of the preceding claims 31,
wherein the base material of the substrate is based on SiC, and wherein the laser source selected in step c) (C) is a CO2 laser providing a laser beam with a laser wavelength of approximately 9.3 μm.

48. Method according to one of the preceding claims 31,
wherein the base material of the substrate is based on SiC, and wherein the laser source selected in step c) (C) is a CO laser providing a laser beam with a laser wavelength of approximately 5.5 μm.

49. Method according to claim 47,
wherein the base material of the substrate consists of SiC.

50. Method according to one of the preceding claims 31,
wherein the base material of the substrate is based on an oxide and/or on Si, and
wherein the laser source selected in step c) (C) is a CO2 laser providing a laser beam with a laser wavelength of approximately 9.3 μm and/or 10.2 μm and/or 10.6 μm.

51. Method according to claim 50,
wherein the base material of the substrate consists of the oxide or of Si.

52. Method according to claim 50,
wherein the oxide is Al₂O₃ or SrTiO₃ or LaAlO₃ or NdGaO₃ or DyScO₃ or MgO or GdScO₃ or Gd₃Ga₅O₁₂ or LiAlO₃ or LiAlO₂ or LiGaO₂ or LiNbO₃ or LiTaO₃ or TbScO₃ or MgAl₂O₄ or SrLaAlO₄ or SrLaGaO₄ or YAlO₃ YSC or LSAT or ZnO or SiO₂ or Ga₂O₃.

53. Method according to one of the preceding claims 31,
wherein the base material of the substrate is based on a nitride, and wherein the laser source selected in step c) (C) is a CO₂ laser providing a laser beam with a laser wavelength of approximately 9.3 μm and/or 10.2 μm and/or 10.6 μm.

54. Method according to claim 53,
wherein the base material of the substrate consists of the nitride.

55. Method according to claim 53,
wherein the nitride is GaN or AlN.

56. Method according to one of the preceding claims 31,
wherein the base material of the substrate is based on a halide, and wherein the laser source selected in step c) (C) is a CO₂ laser providing a laser beam with a laser wavelength of approximately 9.3 μm and/or 10.2 μm and/or 10.6 μm.

57. Method according to claim 56,
wherein the base material of the substrate consists of the halide.

58. Method according to claim 56,
wherein the halide is BaF₂ or CaF₂ or KBr or KCl or NaCl or Mg₂F₂.

59. Substrate heater for heating a substrate, comprising a laser source for providing a laser beam and means for guiding the laser beam to the substrate,
wherein the laser source of the substrate heater is selected according to step a) (A) to c) (C) of the method according to claim 31, and
wherein the substrate heater is constructed to carry out step d) (D) of the method.

60. Thermal laser evaporation (TLE) system, the TLE system comprising a reaction chamber fillable with a reaction atmosphere, a substrate arranged in the reaction chamber, one or more sources arranged in the reaction chamber, and a substrate heater constructed according to claim 59, for providing a laser beam impinging on the substrate and thereby heating the substrate.
